(19) United States
(12) Patent Application Publication
(10) Pub. No.: US 2013/0065397 A1
(43) Pub. Date: Mar. 14, 2013

(54) Methods to increase pattern density and release overlay requirement by combining a mask design with special fabrication processes

(71) Applicant: Yijian Chen, Hercules, CA (US)

(72) Inventor: Yijian Chen, Hercules, CA (US)

(73) Assignee: Vigma Nanoelectronics, Hercules, CA (US)

(21) Appl. No.: 13/199,856

(22) Filed: Sep. 12, 2011

(51) Int. Cl. H01L 21/311

(52) U.S. Cl. 438/703; 257/E21.249

(57) ABSTRACT

A novel process technique and mask design based on the optimized self-aligned triple patterning are invented for the semiconductor manufacturing. This invention pertains to methods of forming one and/or two dimensional features on a substrate having the feature density increased to three times of what is possible using optical lithography, and methods to release the overlay requirement when patterning the critical layers of semiconductor devices.

### BACKGROUND OF THE INVENTION

Optical ArF (wavelength: 193 nm) DUV immersion lithography with NA=1.35 can print half-pitch features as small as 38 nm [1]. Self-aligned double patterning (SADP, [2]) has been widely adopted by the memory industry to extend the life of optical lithography, driving the half pitch down to about 19 nm. Sub-19 nm patterning, however, poses tremendous challenges in lithography, materials, and process technologies. EUV, nano-imprint, and e-beam maskless lithography, all with various manufacturability barriers, will not be ready in time for high-volume manufacturing. To meet the scaling timeline, a self-aligned triple patterning (SATP) technology is proposed recently [3, 4], which can potentially drive the resolution of IC features down to about 13 nm when combined with ArF immersion lithography. It was demonstrated that by adding only one extra CVD/spacer step, the SATP process gains 50% improvement in density compared with a SADP process. By designing various core/mandrel patterns which further define the route of the spacers formed on their sidewall, SATP technique is favorable to reducing process complexity with less masks and allowing more 2-D design flexibility. Nevertheless, the SATP processes reported in references [3, 4] have faced severe processing/material difficulties. For example, a wet etch of the sacrificial layer (e.g., silicon nitride, [3]) resulted in poor line-width roughness (LWR) due to some unknown chemical residues left on top of core/mandrel and the structural spacer. Therefore, new material schemes and processing techniques must be developed to overcome the reported challenges.

In NAND flash wherein positive tone SADP has been widely used, normally the dense arrays and peripheral circuits are decomposed into two separate masks and totally 3 masks (sacrificial core mask, cropping mask, and periphery mask) are needed for one critical layer, as shown in FIG. 1 [2]. On the sacrificial core/mandrel mask, the end of each line is attached to a large rectangle feature such that the following spacers can branch out after the sacrificial core is stripped. Once the cropping step is done, a large enough space will be created between the ends of each pair of spacers. This will help to release the overlay requirement of a SADP process when printing a final pad (using the periphery mask) over the end of each spacer. Such a method to achieve overlay ease, however, does not work for a SATP process. In a SATP process as shown in FIG. 2, the core/mandrel features are not used as sacrificial patterns. Rather, the core/mandrel is kept and the first spacer is used as a sacrificial layer. The second spacer and core become the remaining structures after the first spacer is removed, resulting in spatial frequency or density tripling. Since the space between the core and the second spacer is small (equal to the thickness of the first spacer) in a SATP process, it requires an (impractical) tight overlay control when printing the final pad over the end of each spacer. For example, a misalignment on the order of spacer size can easily cause the final pads to touch the core/mandrel and consequently a connection failure. Therefore, a novel alignment methodology must be developed in order to release the overlay requirement of a SATP process. Keeping this special overlay characteristic in mind helps to understand and appreciate the invention that will be described in more detail below.

### BRIEF SUMMARY OF THE INVENTION

Embodiments of the this invention pertain to methods of forming patterns on a substrate using special mask layouts, having a pitch reduced to one third of the original value defined by a lithographic tool. Based on the combined mask layout and novel processing techniques, a 3-mask process module is developed to pattern complicated 2-D patterns and to release the overlay requirements for patterning critical layers of memory (NAND flash and DRAM) devices. Further applications of the present disclosure will become apparent from the detailed description provided hereinafter.

A number of novel patterning process sequences and the corresponding overlay methodology are developed in accordance with the invention. In one such process, a mandrel layer such as silicon oxide is formed over the substrate, followed by deposition of amorphous carbon and silicon nitride layers. BARC and resist film are then coated and patterned to form the mandrel features. Usually, the resist line CD (critical dimension) that can be successfully printed by optical lithography is significantly larger than what is required by a SATP process. Therefore, a plasma process needs to be applied to trim the resist line CD and to open BARC. After that, the nitride layer is etched and used as a hard mask for the following etching of amorphous carbon. The mandrel patterns formed on amorphous carbon are transferred to the oxide layer underneath. After stripping amorphous carbon by an oxygen plasma, the first (sacrificial) spacers are formed on the sidewalls of oxide mandrels by depositing a sacrificial layer (e.g., polycrystalline or amorphous Si) and etching it back to just remove the sacrificial material deposited on the top surface of oxide mandrels. A second (structural) spacer step will immediately follow the sacrificial spacer step. Many material choices for these two consecutive spacers (referred to as spacer A and B) are possible, provided that they have high etching selectivity to each other. For example, if poly Si is chosen for the first spacer A, nitride can be used for spacer B. As another example, if nitride is chosen for the first spacer A, then polycrystalline or amorphous Si can be used for spacer B. The critical requirement is that spacer A must be wet or dry etched later by a highly selective etch process which does not attack the mandrel and spacer B, resulting in spatial frequency tripling.

In a semiconductor process, each critical layer needs to contain both dense arrays (e.g., lines/spaces and pads) and less dense peripheral patterns to perform designed circuit functions. For example, in NAND flash manufacturing wherein the self-aligned double patterning (SADP) process has been widely used, normally the dense arrays and peripheral circuits (including final pads) are decomposed into separate masks and totally 3 masks (sacrificial core mask, cropping/cut mask, and periphery/pad mask) are needed for one critical layer [2]. Unfortunately, the SADP mask design methodology does not work for a SATP process. As shown in FIGS. 2 and 3, stripping sacrificial spacers A will result in a small gap between the mandrel and spacer B. Such a small gap will create severe difficulty in meeting the overlay requirement of the final pad layer since an alignment inaccuracy can easily cause the final pads connected to wrong lines. To release the overlay requirement of a SATP process, a new process technique must be invented. The key idea of this invention is shown in FIG. 7. First, an extra protective layer is formed on the wafer and patterned with the cropping/cut mask. As shown by the cross-section views cut through the solid line indicated in FIG. 7, an isotropic etch (wet or dry etch which does not attack the structural spacer B) is used to laterally undercut the mandrel layer such that the edge of the mandrel recedes away from the end of structural spacer B. In this manner, a large enough space between the ends of the mandrel layer and the structural spacer is created. Consequently, the overlay requirement of the final pad/periphery mask can be relaxed.

In the other process, minor modification is made to shrink the CD of oxide mandrel by an isotropic (wet or dry) oxide etch after the pattern on amorphous carbon layer is transferred to oxide. This modified process may produce an improved line-width roughness (LWR) of mandrels.

It should be pointed out that the detailed description and specific examples/materials, while indicating various embodiments, are intended for purposes of illustration only and are not intended to limit the scope of the disclosure.

### BRIEF DESCRIPTION OF THE SEVERAL VIEWS OF THE DRAWING(S)

A further understanding of the nature and advantages of the invention may be realized by reference to the specification and the drawings presented below. The figures are incorporated into the detailed description portion of the invention.

FIG. 1, a figure of representing prior art [2], depicts a self-aligned double patterning process and the corresponding mask design.

FIG. 2 illustrates the cross-sectional views representing a self-aligned triple patterning (SATP) process according to one embodiment of the invention.

FIG. 3 illustrates the cross-sectional views representing another self-aligned triple patterning (SATP) process according to the other embodiment of the invention.

FIG. 4 is a flowchart depicting steps associated with the SATP process described by FIG. 2.

FIG. 5 is a flowchart depicting steps associated with the SATP process described by FIG. 3.

FIG. 6 are top views associated with the 3-mask layout required by a SATP process. Less dense 2-D peripheral features resolvable by single-exposure optical lithography (not shown in the figure) can be patterned together with the final pads using the same pad/periphery mask.

FIG. 7 are top and cross-sectional views associated with the mask layout and processing techniques to release the overlay requirement of a SATP process.

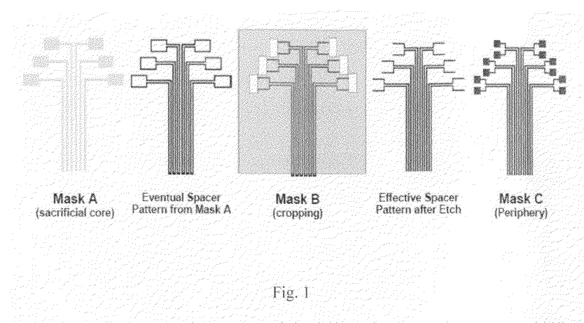

### DETAILED DESCRIPTION OF THE INVENTION

Embodiments of the present invention pertain to methods of forming patterned features on a substrate having a pitch reduced to one third of what is achievable using standard lithographic techniques. Compared with self-aligned double patterning (SADP) process which has been used in the production of high density 1-D lines/spaces, the invented technique significantly increases the feature density by using a slightly more complex process. While this technique can form bit lines, wider lines and features (e.g., line-end pads, power supply lines, string select lines in NAND devices, etc.) are usually necessary on same layer to form working devices, which requires multiple masks to be used to pattern one critical layer. Therefore, it is important to research a mask design method that not only allows reasonable (i.e., not too tight) overlay specifications, but also requires the minimum number of masks to reduce the process complexity and costs.

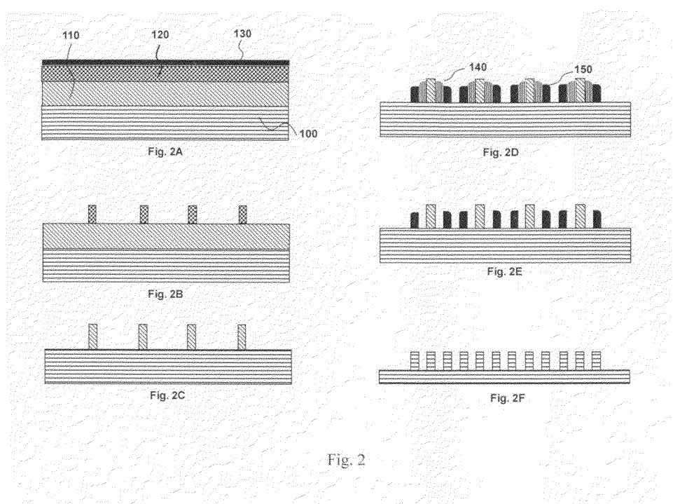

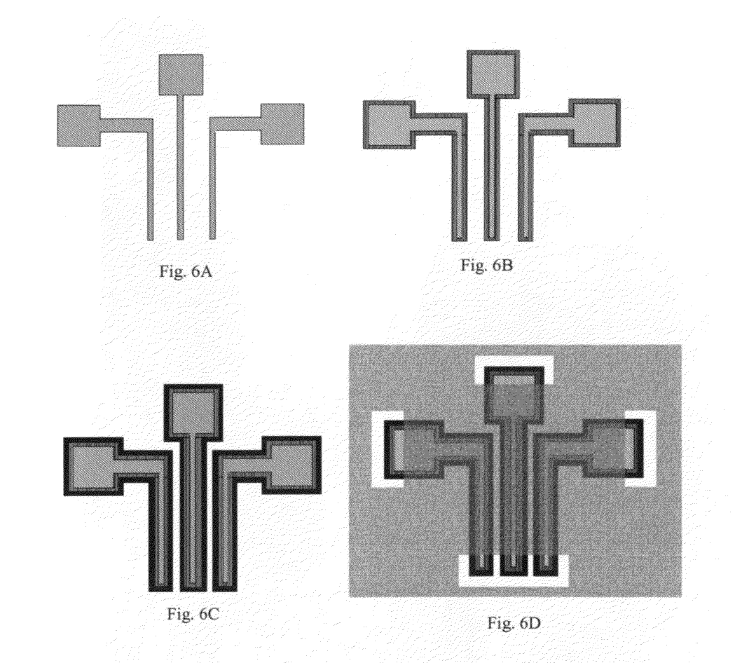

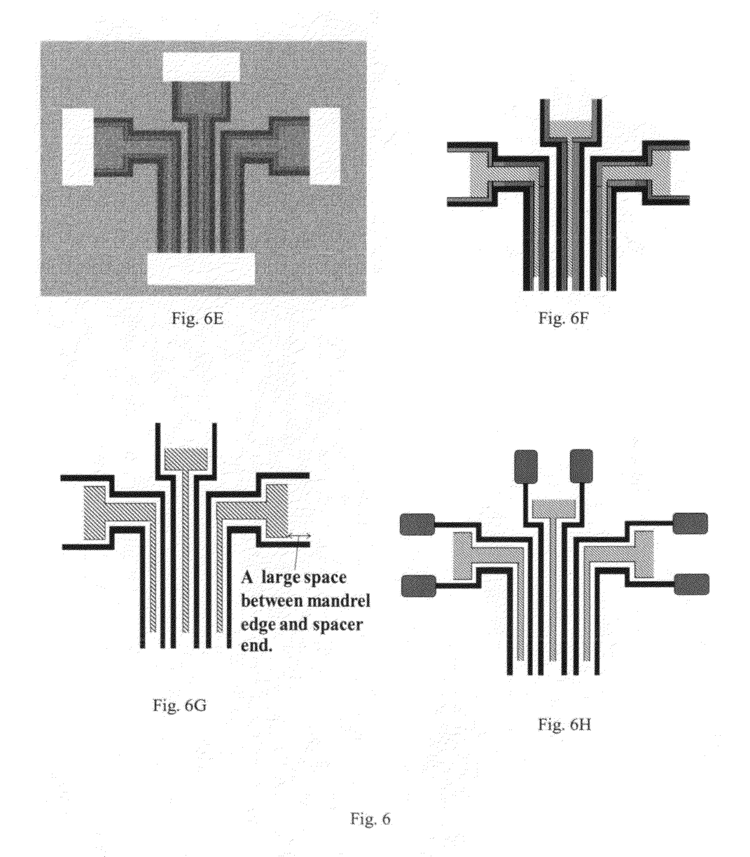

To better understand and appreciate the invention, a flowchart is shown in FIG. 4 to depict the steps associated with the patterning process according to one embodiment of the invention. The correspondingly cross-sectional views cutting through the array structure are shown in FIGS. 2A-F to illustrate the process details in above flowchart. The method starts by forming a stack of layers on a substrate 100 as shown in FIG. 2A. It is also described by operations 352-356 in the flow chart. This stack of layers includes a silicon oxide layer 110, an amorphous carbon layer 120, and a hard-mask layer 130 (e.g., silicon nitride). The hard mask layer 130 is patterned by the optical lithography (operation 358) and the half pitch of patterned features is defined by the minimum resolution of a lithographic tool (e.g., about 38 nm with ArF DUV immersion lithography). The clear-field mask pattern of lithography 1 is shown in FIG. 6A. For the purpose of drawing convenience, only three lines are drawn in FIG. 6A while the actual number of lines can be arbitrary in semiconductor manufacturing. Due to the limitation of optical lithography, it is difficult to directly print sub-20 nm lines on resist. Therefore, a plasma process to trim the resist and BARC CD (operation 360) will be performed first. The shrunk pattern on resist is then transferred to nitride and later etched into the amorphous carbon layer underneath (operation 362, using nitride as a hard mask to etch amorphous carbon). After the pattern is transferred down to the oxide layer (operation 364), amorphous carbon residues are stripped by an oxygen plasma process (operation 366). A sacrificial layer 140 (e.g., polycrystalline or amorphous Si) is then deposited on top of oxide mandrels and (optionally) etched back (operation 368) to form Si spacers on the sidewalls of the oxide mandrels, as shown in FIG. 6B. The second (structural) spacer 150 (e.g., boron doped high-density nitride or any other material that can survive in the mandrel undercut process to be described below) will be formed directly on the sidewalls of Si spacers, as shown in FIG. 2D.

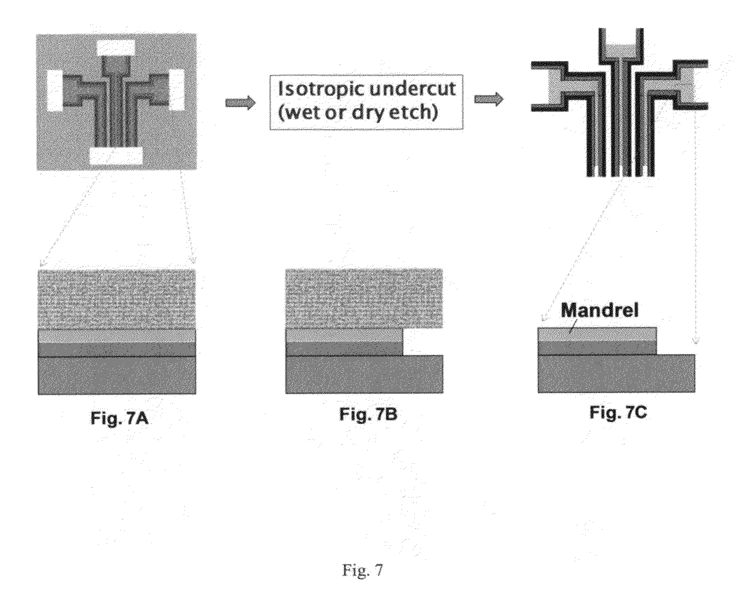

As shown in FIGS. 2D and 6C, the width of sacrificial spacer 140 will define a small gap between the oxide mandrel and the structural spacer 150. Such a small gap will create severe difficulty in meeting the overlay requirement for patterning the final pad layer. It is straightforward to image that an alignment inaccuracy can easily cause the final pads to touch wrong lines. To avoid this problem and release the overlay requirement of a SATP process, a new process technique is invented and the key idea is shown in FIG. 7. First, an extra protective layer is formed on the wafer (operation 372) and patterned with the cut/cropping mask (operations 374 and 376). The cut/cropping mask layout is shown in FIG. 6E. The protective layer in the opening area is etched, and the exposed mandrel and spacers are then removed. It should be kept in mind that the protective layer must be thick enough such that it is not completely removed during above etching processes. As illuminated by the cross-sectional views cutting through the solid line indicated in FIG. 7, an isotropic etch (operation 378, wet or dry etch which does not attack the structural spacer 150) is used to laterally undercut the mandrel layer such that the edge of the mandrel recedes away from the end of structural spacers. It is also helpful to refer to the top views of FIG. 6F to understand the process details. Once the lateral undercut of the mandrels is completed, the remaining protective layer is stripped and the sacrificial spacers are removed (operation 380) by a dry plasma process. After the sacrificial spacers are removed, a large enough space between the edge of a mandrel and the end of a structural spacer is created, as shown in FIG. 6G. Consequently, the overlay requirement of the final pad/periphery mask can be relaxed. Compared with the method of using wet solution to etch sacrificial spacers [3], a dry plasma process helps to improve the line-edge roughness of both mandrels and structural spacers. Finally, a third lithographic step (lithography 3, operation 382) will print a pad over the end of each spacer for contact landing (the end of each mandrel line already has a recessive pad formed in the first lithographic step). The pattern of the line array with pads can be transferred to the substrate (operation 384) if necessary.

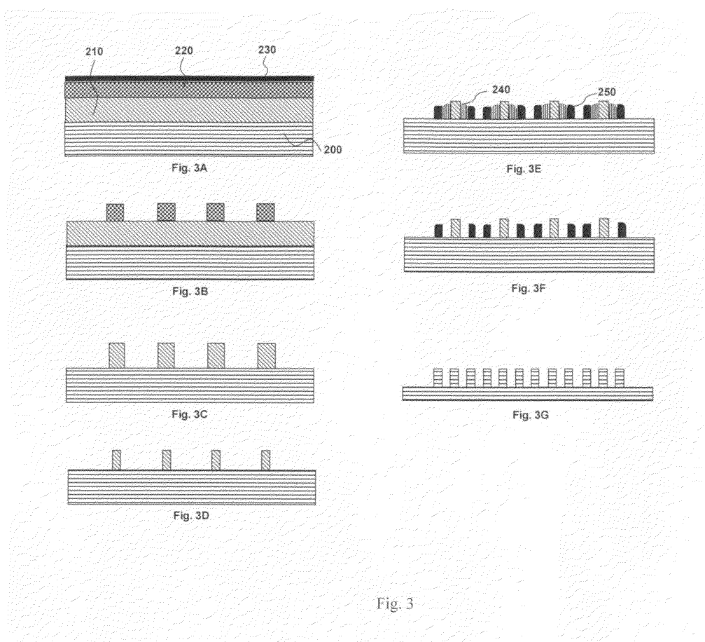

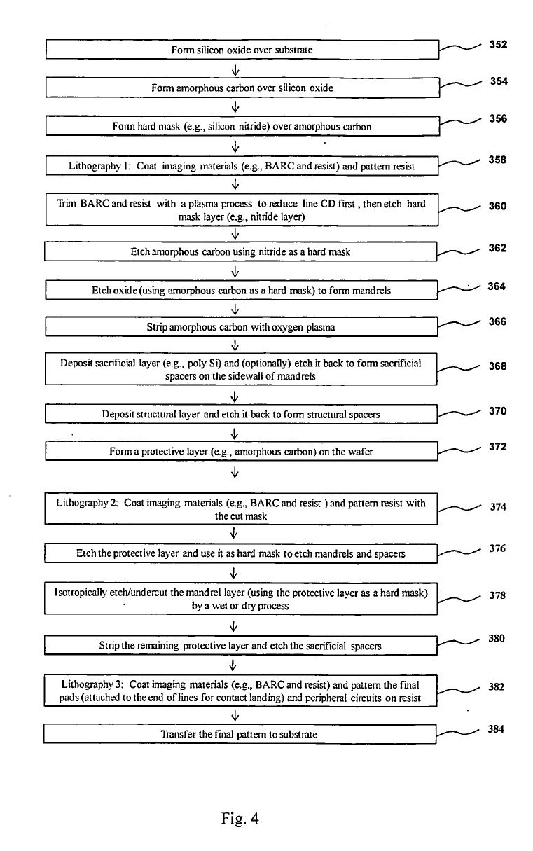

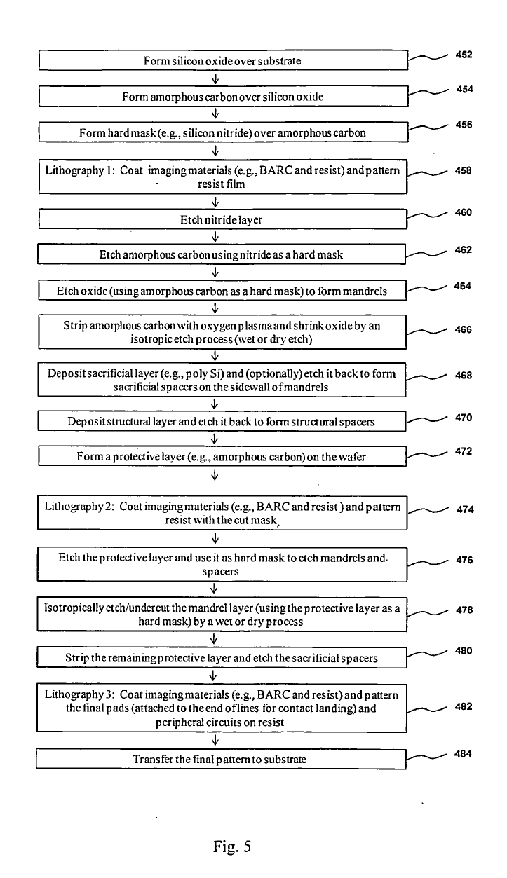

Another flowchart is shown in FIG. 5 to depict the steps associated with a slightly different process. The corresponding cross-sectional views cutting through the array structure (lines/spaces) are shown in FIGS. 3A-G to illustrate the process details of the steps in this flowchart. Instead of carrying out a resist/BARC trimming to shrink line CD, minor process modification is made. In this new process, we shrink the oxide mandrel CD by an isotropic (wet or dry) oxide etch after the pattern on amorphous carbon is transferred to the oxide layer. This modified process may produce an improved line-width roughness (LWR) of the mandrels. For example, a treatment of oxide mandrels in a diluted HF solution can reduce the mandrel CD and smooth out the high-frequency components of line-edge roughness.

Apparently, the uniqueness of the invention is: design a SATP process that can avoid the residue problems related with wet etch of the mandrels (reported in previous literatures); and more importantly, a novel processing technique and special mask layout that can be combined together to release the overlay requirement of a SATP process.

### REFERENCES

[1] International Technology Roadmap for Semiconductors (ITRS), 2009 version.

[2] C. Bencher, Y. M. Chen, H. Dai, W. Montgomery, L. Huli, “22 nm Half-Pitch Patterning by CVD Spacer Self Alignment Double Patterning (SADP)”, Proc. SPIE Vol. 6924, 69244E, 2008.

[3] Y. Chen, P. Xu, Y. M. Chen, L. Miao, X. Xu, C. Bencher, C. Ngai, “Self-aligned triple patterning to extend optical lithography for 1×patterning,” The International Symposium on Lithography Extensions, Kobe, Japan, Oct. 20-22, 2010.

[4] B. Mebarki, H. Chen, Y. M. Chen, A. Wang, J. Liang, K. Sapre, T. Mandrekar, X. Chen, P. Xu, P. Blanko, C. Nhai, C. Bencher, M. Naik, “ Innovative self-aligned triple patterning for 1×half pitch using single spacer deposition-spacer etch step”, Proc. of SPIE, Vol. 7973, 79730G, 2011.

1. A novel patterning process and the corresponding 3-mask layout design comprising:
a first layer of a mandrel material formed over the substrate;
an amorphous carbon layer formed over the mandrel layer;
a hard-mask layer formed over the amorphous carbon layer;
a lithographic step (lithography 1) to pattern resist coated on wafer;
etching the hard-mask layer;
etching the amorphous carbon layer;
etching the mandrel layer;
stripping amorphous carbon residues;
(optionally) shrinking mandrel CD by an isotropic etch process;
deposition of a CVD (chemical vapor deposition) sacrificial layer over the mandrel features;
(optionally) etching the CVD layer to form sacrificial spacers on the sidewall of mandrel features;
deposition of a CVD structural layer on top of sacrificial spacers;
etching the structural layer to form the second (structural) spacers;
a protective layer formed on the wafer, followed by BARC and resist coating;
a lithographic step (lithography 2) to pattern resist using the cut/cropping mask;
etching the protective layer;
etching the mandrels and both spacers;
isotropic etching to laterally undercut the mandrels;
stripping the protective layer;
a lithographic step (lithography 3) to pattern resist using the pad/periphery mask;
etching to transfer the final pattern to the substrate.

1. The method of claim 1 wherein the mandrel material is silicon oxide.

3. The method of claim 1 wherein the mandrel CD is shrunk by a buffered HF solution.

4. The method of claim 1 wherein the mandrel CD is shrunk by an isotropic dry etch process.

5. The method of claim 1 wherein the sacrificial layer is polycrystalline or amorphous Si.

6. The method of claim 1 wherein the structural layer is silicon nitride.

7. The method of claim 1 wherein the protective layer (formed before the second lithographic step) is amorphous carbon.

8. The method of claim 1 wherein the lateral undercut of oxide is done using a buffered HF solution.

9. The method of claim 1 wherein the lateral undercut of oxide is done using an isotropic dry etch process.
